(19) United States
(12) Patent Application Publication
(10) Pub. No.: US 2013/0082357 A1
(43) Pub. Date: Apr. 4, 2013

(54) PREFORMED TEXTURED SEMICONDUCTOR LAYER

(71) Applicants: Ibrahim Alhomoudi, Yorktown Heights, NY (US); Stephen W. Bedell, Wappingers Falls, NY (US); Keith E. Fogel, Hopewell Junction, NY (US); Paul A. Lauro, Brewster, NY (US); Ning Li, Yorktown Heights, NY (US); Devendra K. Sadana, Pleasantville, NY (US); Davood Shahrjerdi, Ossining, NY (US)

(72) Inventors: Ibrahim Alhomoudi, Yorktown Heights, NY (US); Stephen W. Bedell, Wappingers Falls, NY (US); Keith E. Fogel, Hopewell Junction, NY (US); Paul A. Lauro, Brewster, NY (US); Ning Li, Yorktown Heights, NY (US); Devendra K. Sadana, Pleasantville, NY (US); Davood Shahrjerdi, Ossining, NY (US)

(73) Assignee: INTERNATIONAL BUSINESS MACHINES CORPORATION, Armonk, NY (US)

(21) Appl. No.: 13/253,059

(22) Filed: Oct. 4, 2011

(51) Int. Cl. H01L 29/16; H01L 29/04; H01L 21/60

(52) U.S. Cl. 257/616; 438/118; 257/613; 257/627; 257/E29.082; 257/E29.004; 257/E21.506

(57) ABSTRACT

A base layer of a semiconductor material is formed with a naturally textured surface. The base layer may be incorporated within a photovoltaic structure. A controlled spalling technique, in which substrate fracture is propagated in a selected direction to cause the formation of facets, is employed. Spalling in the [110] directions of a (001) silicon substrate results in the formation of such facets of the resulting base layer, providing a natural surface texture.

### FIELD OF THE INVENTION

The present invention relates to the physical sciences, and, more particularly, to photovoltaic structures.

### BACKGROUND OF THE INVENTION

In the field of photovoltaics, an important property of a solar cell is how efficiently light is absorbed by the semiconductor material. The absorption of light, typically sunlight, can be enhanced by: 1) applying a layer of anti-reflective coating (ARC) on the surface of the semiconductor and/or 2) “texturing” the surface of the semiconductor to help trap light via multiple reflections. Surface texturing usually involves a chemical treatment step that etches a surface of the semiconductor anisotropically wherein some crystallographic planes are etched faster than others. This results in an array of pyramidal surface features for <100> silicon.

### SUMMARY OF THE INVENTION

Principles of the invention provide techniques for improving solar cell performance and facilitating the manufacture of solar cell structures. In one aspect, an exemplary method includes the step of obtaining a semiconductor substrate having a dominant crystallographic orientation and comprising natural fracture planes and a first surface. A tensile stressed metal layer is adhered to the semiconductor substrate over the first surface. A fracture is propagated beneath and substantially parallel to the first surface of the substrate in a direction that intersects the natural fracture planes of the semiconductor substrate such that a semiconductor layer having a natural surface texture is formed on a second surface of the semiconductor layer. The semiconductor layer and tensile stressed metal layer are separated from the semiconductor substrate. A structure comprising a semiconductor base layer having a natural texture is further provided in accordance with the invention.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

Techniques of the present invention can provide substantial beneficial technical effects. For example, one or more embodiments may provide one or more of the following advantages:
Enhanced light trapping;
Reduction of optical loss due to reflection;
No loss of substrate material in creating a textured surface;
A fast, low-cost alternative to chemical-based texturing.

These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 schematically illustrates silicon crystal including Miller indices and proposed fracture planes;

FIG. 2 is a top plan view of a silicon wafer showing two possible spalling directions;

FIG. 3 illustrates the spalling of the silicon wafer in a first direction at forty-five degrees with respect to the [110] directions;

FIG. 4 illustrates the spalling of the silicon wafer in a second direction along the [110] directions;

FIG. 5 is a sectional view showing the silicon wafer following the spalling technique shown in FIG. 3, and

FIG. 6 is a sectional view showing the silicon wafer following the spalling technique shown in FIG. 4.

### DETAILED DESCRIPTION OF PREFERRED EMBODIMENTS

Spalling is a technique that may be employed to obtain a layer from a semiconductor substrate. This technique involves causing a fracture to form in the substrate. In accordance with an aspect of the invention, the direction of spalling mode fracture propagation is such that the crack front intercepts the natural fracture plane of a semiconductor substrate having a crystalline structure or a large grain (or highly textured) multi-crystal structure. In a preferred embodiment, interaction with the natural fracture plane of the crystalline structure is maximized to create a natural surface texture on the layer of silicon obtained from the substrate. Surface texturing of semiconductors can enhance the trapping of light and reduce optical loss due to reflection.

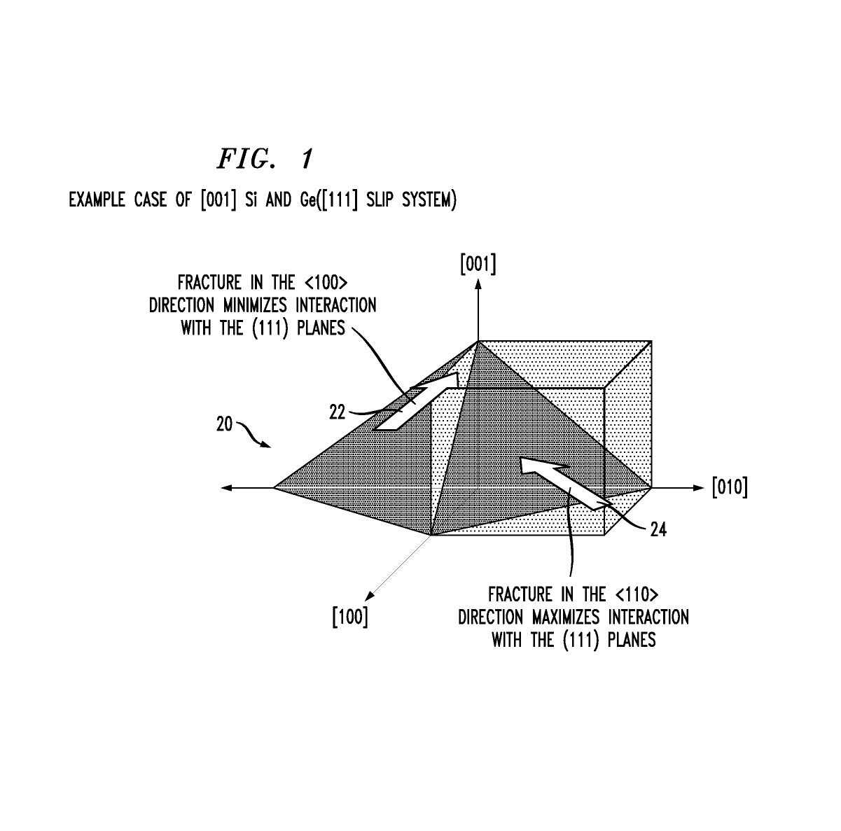

The lattice planes and lattice directions of crystalline semiconductor materials can be described by Miller indices. Referring to FIG. 1, a substrate 20 of single-crystalline silicon and three crystal directions [001], [010] and [100] are shown. Single crystal wafers can be provided with flats to denote the orientation of a crystal and its doping. For example, <100> n-type silicon wafers may include a primary (relatively large) flat and a secondary (relatively small) flat one hundred eighty degrees apart. Silicon is anisotropic, and its atomic arrangement varies when viewed in different directions. The two arrows 22, 24 in FIG. 1 designate two possible directions <100> and <110> of fracture, respectively, of the substrate 20 employing spalling techniques in accordance with the invention.

Surface layer removal can be controlled in accordance with the techniques described herein such that a fracture in a substrate propagates below and parallel to a selected surface of the substrate, allowing a layer of substrate material to be removed. The direction of spalling can also be controlled. Such spalling techniques allow the thickness and surface characteristics of the removed layer to be controlled by the manufacturer. In accordance with a preferred embodiment of the invention, a surface of the removed layer is formed with a natural surface texture that enhances the trapping of light without the need for subsequent surface treatments such as etching.

In an exemplary embodiment, the spalling technique employed to provide a desired surface texture involves depositing a layer of metal under tensile strain on a selected surface of a substrate. An adhesion layer may be employed to secure the metal (e g. nickel) stressor layer to the substrate. The adhesion layer may also be metal, such as chromium or titanium. A foil is adhered to the surface of the stressor layer. The foil may be comprised of a metal or a polymer (such as polyimide) and has sufficient flexibility to allow the controlled spalling process to be implemented. It is preferred that the spalling process employed in accordance with the invention be controlled as opposed to spontaneous.

Publication No. US 2010/0311250 entitled “Thin Substrate Fabrication Using Stress-Induced Substrate Spalling”, the disclosure of which is incorporated by reference herein in its entirety, discloses techniques resulting in spontaneous spalling as well as non-spontaneous, controlled spalling of semiconductor substrates. As discussed therein, the thickness of the deposited metal layers affects whether spalling will be spontaneous at room temperature or require mechanical assistance. Relatively thin metal layer(s) are employed to facilitate controlled as opposed to spontaneous spalling. The controlled spalling technique allows the fracture in the substrate to be propagated in selected directions. Exemplary embodiments disclosed in the publication relate to the fracture of a crystalline silicon substrate in any of four ([001], [−100], [010], [0−1—]) directions orthogonal to the cleavage directions [110]. The disclosed technique is said to work well on substrates comprising GaAs, Si, and Ge, as well as all substrates having crystal orientation <100> and <111>. The controlled spalling techniques disclosed in Publication No. US 2010/0311250 can be adapted, as discussed below, to produce a semiconductor layer having a natural surface texture.

A controlled spalling technique is also disclosed in Publication No. US 2010/0310775 entitled “Spalling for a Semiconductor Substrate.” This technique involves obtaining an n-type or p-type ingot, forming a seed layer (e.g. Pd or Ti) on the ingot if it is p-type, forming an adhesion layer on the seed layer or ingot, forming a tensile stressed metal layer on the adhesion layer, and removing a layer from the ingot via spalling. The publication indicates that fracture may be improved in terms of roughness and thickness uniformity if the fracture is oriented along the natural cleavage plane of the material comprising the ingot (111 for Si and Ge). The disclosure of this publication is also incorporated by reference herein.

Publication No. US 2010/0307572 of Bedell et al. entitled “Heterojunction III-V Photovoltaic Cell Fabrication” is further incorporated by reference in its entirety herein. This publication discloses a controlled, low-temperature spalling technique for obtaining thin layers (e.g. twenty microns or less) from a III-V substrate (e.g. Ge or GaAs) as part of a process for fabricating single or double heterojunction photovoltaic cells. In one embodiment, a back surface field (BSF) layer is formed on a III-V substrate and a tensile stressed metal layer formed over the BSF layer. A thin base layer and the BSF layer are spalled from the substrate using a flexible substrate adhered to the tensile stressed layer. In another embodiment, an intrinsic semiconductor layer, a BSF layer and an amorphous silicon layer are formed on a III-V substrate. A tensile stressed metal layer is formed over the amorphous silicon layer and a flexible substrate is adhered to the metal layer. Using the flexible substrate and tensile stressed metal layer, a spalling process is employed to fracture the substrate, thereby separating a thin III-V base layer from the substrate as well as the intrinsic layer, BSF layer and amorphous silicon layer that were previously associated with the substrate. Following removal of the flexible substrate from the metal layer, an intrinsic semiconductor layer, amorphous silicon layer and transparent conductive layer (a transparent conductive oxide layer) are formed, respectively, on the base layer to form a double heterojunction structure. The controlled, low-temperature spalling technique disclosed in Publication No. US 2010/0307572 can be adapted, in accordance with the principles of the invention, to provide a naturally textured surface on the thin base layer by non-spontaneous spalling of the III-V substrate in a direction that facilitates texturing.

A preferred method in accordance with the present invention, like that disclosed in Publication No. US 2010/0311250, involves the deposition of a thin metal layer such as tensile strained nickel on the substrate at low temperature (less than 300° C.). The thickness of the stressor layer, which may be comprised of a plurality of metal layers, is determined by the desired thickness of the semiconductor layer to be removed. The stressor layer thickness and stress value are also in ranges that spontaneous spalling is avoided. The stressor layer thickness may fall in the range of one to fifty microns. A metal adhesion layer may optionally be provided on the substrate prior to stressor layer deposition. A flexible membrane such as polyimide is adhered to the surface of the stressor layer and functions as a handle layer that can be used for exerting mechanical force on the stressor layer. Prior to bonding the flexible membrane, a fracture initiation region may be created by laser scribing or any other suitable technique between the substrate and the semiconductor layer to be removed from the substrate. The flexible membrane is pulled away from the substrate and in a selected direction to remove the assembly comprising the semiconductor layer and stressor layer from the substrate. The semiconductor layer will be within a specified thickness range that can be controlled in the manner discussed above. It can also exhibit a natural texture that is controlled by the direction of propagation of the fracture. The natural texture is unlike that obtained through etching the substrate surface, and is obtained as a result of what is believed to be competition between the fracture parallel to the crystal surface caused by the spalling technique and a trajectory along the natural fracture planes. There will be both a geometric difference in the semiconductor layer surface as compared to the surface obtained by crystallographic etching as well as non-periodicity achieved through spalling-induced texture. The assembly comprising the semiconductor layer and stressor (e.g. nickel) layer can be transferred at room temperature to another substrate or otherwise processed.

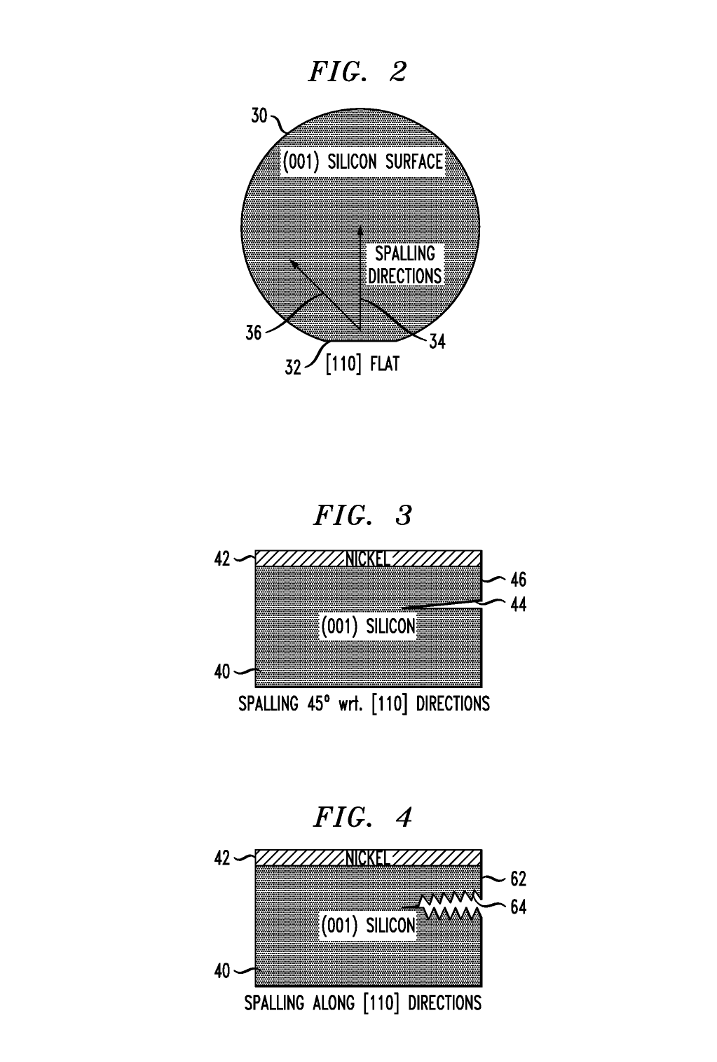

FIG. 2 shows a (001) silicon wafer 30 having a [110] flat 32. The two arrows 34, 36 represent spalling directions using a spalling technique as described above. One of the arrows shows a spalling direction along the [110] direction. The second arrow 36 shows a direction 45° with respect to the [110] direction, i.e. the [100] direction.

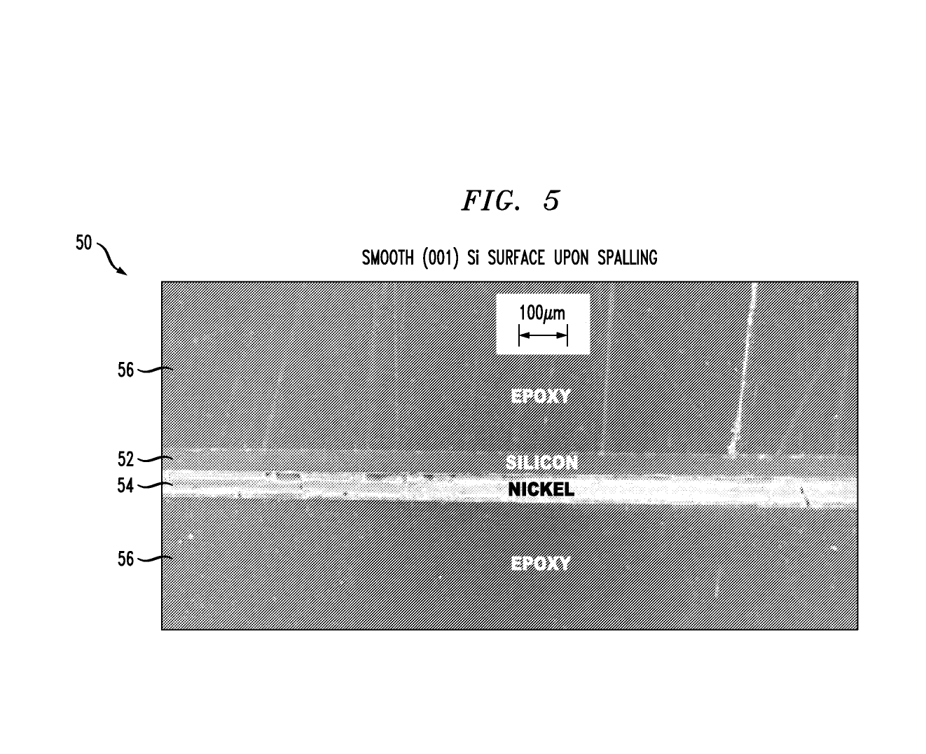

FIG. 3 is a sectional view illustrating spalling of a (001) silicon substrate 40 45° with respect to the [110] direction. A mechanical force is exerted on a nickel layer 42 bonded to the substrate during the spalling process. A polyimide foil layer (not shown) adhered to the nickel layer 42 as described above may be employed to apply the force necessary to effect propagation of the fracture. The fracture in the silicon substrate results in smooth silicon surfaces 44 along the fracture. Fracturing in this direction is believed to minimize interaction with the (111) planes, which are the natural fracture planes of crystalline silicon and germanium. The silicon layer 46 that is ultimately separated from the substrate 40, having a surface without effective texturing, may accordingly tend to reflect light rather than absorb it. FIG. 5 shows a solar cell structure 50 made using the technique shown in FIG. 3 with a (001) silicon wafer as the starting substrate. The silicon layer 52 has a smooth surface that is evident under magnification. In this exemplary embodiment, the silicon and adjoining nickel layers 52, 54 are embedded in epoxy 56 as a means to form a cross-sectional image. As the spalling technique described above allows thin layers of silicon to be obtained from the substrate, flexible solar cell structures are feasible when the silicon and adjoining metal layer are separated therefrom.

The silicon layer 52 is less than fifty microns in thickness. FIG. 4 shows a second exemplary spalling technique wherein spalling takes place along the [110] direction as indicated by arrow 32 in FIG. 2. As in FIG. 2, the starting substrate 40 is a (001) silicon wafer. Unlike the silicon surface obtained in FIG. 2, a silicon layer 62 having a textured surface 64 is obtained. It has been found that when the direction of fracture is substantially parallel to the projection of the natural fracture plane onto the plane of the resulting surface, the fracture tends to follow a path that includes the natural fracture planes. In other words, cracks are allowed to propagate up and down as the fracture moves through the crystal, but it tends not to “tilt”. Therefore, when the natural fracture planes (such as the (111) planes in c-Si and c-Ge) are aligned such that fracture along them is transverse to the crack propagation direction, textured surfaces 64 will result. In this exemplary embodiment, it is believed that fracture in the [110] direction maximizes interaction with the (111) planes. By having surface texturing become an integral part of a starting photovoltaic substrate, subsequent loss of semiconductor material by etching or the like can be avoided. Additionally, because surface texturing is a natural consequence of spalling mode fracture if conducted in an appropriate manner, a wide range of material systems can be created with surface texturing. While the example provided herein concerns crystalline silicon, the principles of the invention are applicable to other semiconductor materials, including III-V compound materials that are not ordinarily textured due to the expense of growing layers of such materials. Additional semiconductor materials that may be provided with a natural texture include all elemental semiconductors (e.g. Si, Ge, diamond) as well as the III-V and II-VI compound semiconductor crystals (e.g. GaAs, GaP, GaN, SiC).

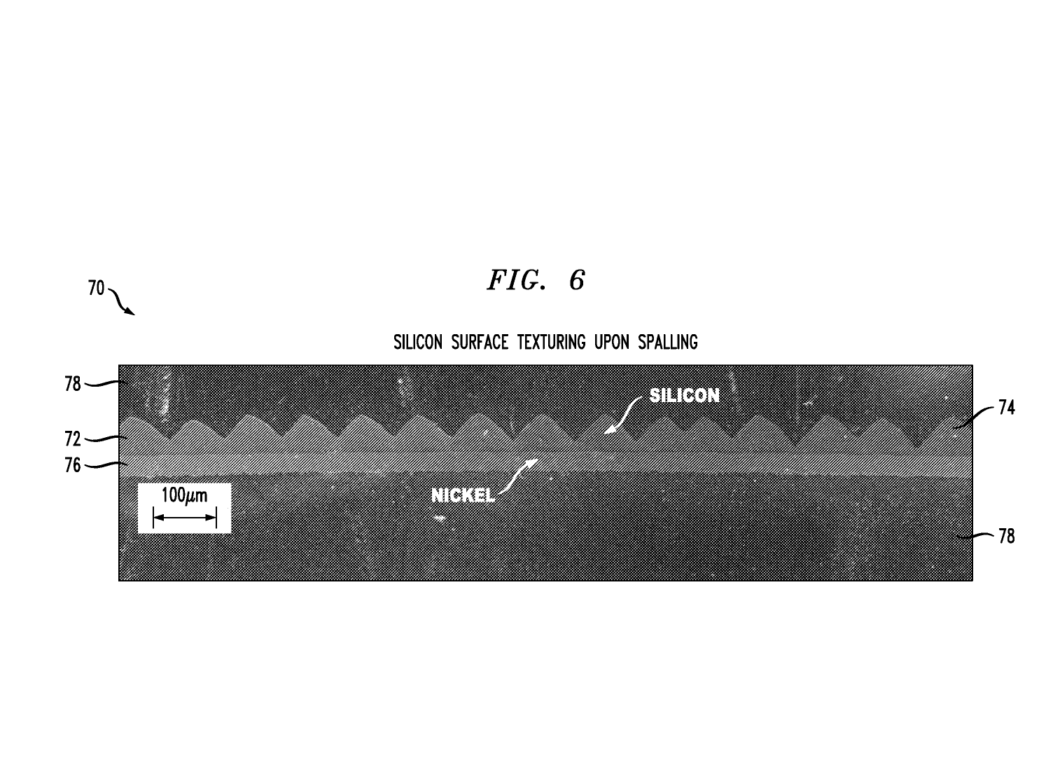

FIG. 6 shows a solar cell structure 70 including a silicon layer 72 having a naturally textured surface 74 formed by the spalling method described above with respect to FIG. 4. The preferred texture range is from 10 to 50 μm peak to valley; experimentally this can be seen in FIG. 6. Roughness of the textured surface has been found to be largely independent of external variables. Generally, however, faster spalling speeds tend to reduce roughness. The silicon layer in this exemplary structure is bounded by a nickel layer 76. The silicon and nickel layers are within epoxy layers 78 for the purpose of imaging the samples in cross-section. The non-periodicity of the textured surface 74 and the (111) facets are evident in the magnified sectional view provided by this figure. The structure shown in FIG. 6, absent the epoxy layers, is a substrate upon which photovoltaic (P V) assemblies can be fabricated. For instance, if these layers contained p/n junctions or heterostructures, then they would operate as PV cells (after forming fingers/bus bars and contacts).

The solar cell structure 70 comprising the silicon base layer and tensile stressed metal layer may be employed in fabricating finished or unfinished photovoltaic structures. For example, the textured surface 74 could be attached to a semiconductor with a different doping type or concentration than the base layer. The textured surface could be attached to doped junctions, intrinsic or doped hydrogenated a-Si_{1-x-y}GeₓC_{y}, a single- or multi-layer insulator for surface passivation and/or anti-reflection coating or a metallic contact layer. Doped junctions may be formed through deposition or diffusion. Deposited doped junctions may be amorphous, nanocrystalline, microcrystalline, poly-crystalline or single-crystalline. The doping type of the doped junctions can be the same or the opposite of the textured layer to form either the emitter or back-surface field. Deposited doped junctions can be graded, multi-layer and different from the textured material. Doped junctions can be either continuously or locally formed. The textured surface can be attached to a combination of the above.

While the present invention has been described above with respect to crystalline silicon and germanium substrates, the principles of the invention are applicable to other semiconductor substrates having a dominant crystallographic orientation. There are a large class of substrates that fit into this category (e.g. single crystal, microcrystalline, highly-textured polycrystalline, and monocast silicon. The preferred direction of spalling is the direction that is parallel to the projection of the natural fracture plane onto the plane of the substrate surface. If the projection is given by P and the natural fracture plane is given by S and the unit normal vector to the surface is given by N, then the preferred spalling direction D is given by; P=S−(S·N)*N. As an example, if the surface orientation of a Si crystal is (001) and the natural fracture plane is (111), then P=(111)−((111)·(001))*(001)=(111)−(001)=(110). Therefore, the (110) direction is the preferred direction to maximize texturing. The same procedure would be followed for other orientations (where X-Ray diffraction could be used to identify the crystallographic directions), and other crystals where cleavage could be used to determine the natural fracture planes (e.g., (110) for GaAs).

Given the discussion thus far, it will be appreciated that, in general terms, an exemplary method, according to an aspect of the invention, includes the step of obtaining a semiconductor substrate having a dominant crystallographic orientation comprising natural fracture planes and a first surface. As discussed above with respect to FIGS. 2, 4 and 6, the semiconductor substrate can be a (001) silicon wafer. Crystalline silicon has natural (111) fracture planes. The method further includes adhering a tensile stressed metal layer to the semiconductor substrate over the first surface. As discussed above, this layer may be adhered directly or indirectly to the semiconductor substrate. A fracture is propagated beneath and substantially parallel to the first surface of the substrate in a direction that intersects the natural fracture planes of the semiconductor substrate such that a semiconductor layer having a natural surface texture is formed on a second surface of the semiconductor layer. The assembly comprising the semiconductor layer and tensile stressed metal layer is separated from the semiconductor substrate when fracturing is complete. As discussed above, various layers may be attached to the textured surface depending on the intended use of the assembly. In one particular example where the semiconductor layer is a III-V material such as GaAs, an intrinsic semiconductor layer may be attached to the textured surface.

An exemplary structure according to the invention is provided including a thin semiconductor layer having a natural surface texture on one surface. Such a structure includes a base layer comprising a semiconductor material having a dominant crystallographic orientation and a thickness of one hundred microns or less. A tensile stressed metal layer is adhered to the base layer above a first surface of the base layer. The second surface of the base layer comprises a naturally formed texture comprised of a plurality of facets defined by natural fracture planes within the semiconductor material. As discussed above, the surface texture of a base layer obtained by the spalling technique disclosed herein is different from the surface texture obtained when a base layer is etched. A non-periodicity is associated with spalling-induced texture. Alternatively, as described in Pub. No. US 2010/0307572 wherein a III-V base layer is employed, an intrinsic semiconductor layer may adjoin the textured surface of the base layer formed in accordance with the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof Terms such as “above” and “below” generally refer to relative positions of elements rather than relative elevations unless otherwise indicated.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method comprising:
obtaining a semiconductor substrate having a dominant crystallographic orientation and comprising natural fracture planes and a first surface;
adhering a tensile stressed metal layer to the semiconductor substrate over the first surface;
causing a fracture to propagate beneath and substantially parallel to the first surface of the substrate in a direction that intersects the natural fracture planes of the semiconductor substrate such that a semiconductor layer having a natural surface texture is formed on a second surface of the semiconductor layer, and
separating the semiconductor layer and tensile stressed metal layer from the semiconductor substrate.

2. The method of claim 1, further comprising:
adhering one or more intermediate layers to the first surface of the semiconductor substrate and adhering the tensile stressed metal layer to one of the intermediate layers.

3. The method of claim 1, wherein the semiconductor substrate comprises single crystal silicon (001) and wherein the direction of fracture is the <110>direction.

4. The method of claim 1, wherein the semiconductor substrate comprises single crystal germanium (001) and wherein the direction of fracture is the <110>direction.

5. The method of claim 1, further including operatively associating a handle foil with the tensile stressed metal layer, applying force to the handle foil to separate the semiconductor layer and tensile stressed metal layer from the semiconductor substrate.

6. The method of claim 5, further including separating the handle foil from the tensile stressed metal layer following separation of the semiconductor layer from the semiconductor substrate.

7. The method of claim 1, wherein the semiconductor layer has a thickness of less than one hundred microns.

8. The method of claim 1, wherein the natural surface texture has a peak to valley range between 10-50 μm.

9. The method of claim 1, wherein the step of causing a fracture in the semiconductor substrate is conducted at room temperature.

10. The method of claim 7, wherein the semiconductor substrate is comprised of a direct gap III-V material.

11. The method of claim 10, further including the step of attaching an intrinsic semiconductor layer to the second surface of the semiconductor layer.

12. The method of claim 7, wherein the semiconductor substrate is comprised of a large grain multi-crystal material.

13. The method of claim 7, further including the step of attaching a doped junction to the second surface of the semiconductor layer.

14. The method of claim 13, wherein the doped junction and the semiconductor layer have the same doping type.

15. The method of claim 14, wherein the doped junction and the semiconductor layer have opposite doping types.

16. A structure comprising:
a base layer comprising a semiconductor material having a dominant crystallographic orientation and a thickness of one hundred microns or less, the base layer having first and second surfaces;
a tensile stressed metal layer adhered to the base layer above the first surface;
a third layer adjoining the second surface of the base layer;
the second surface of the base layer comprising a naturally formed texture comprised of a plurality of facets defined by natural fracture planes within the semiconductor material.

17. The structure of claim 16, wherein the semiconductor material is single crystal silicon (001) and the facets are along (111) planes.

18. The structure of claim 16, wherein the semiconductor material is single crystal germanium and the facets are along (111) planes.

19. The structure of claim 16, wherein the naturally formed texture of the second surface of the base layer is from 10 to 50 μm peak to valley.

20. The structure of claim 17, wherein the naturally formed texture of the second surface of the base layer is from 10 to 50 μm peak to valley.

21. The structure of claim 16, wherein the third layer comprises an intrinsic semiconductor layer.

22. A structure comprising:
a base layer comprising a semiconductor material having a dominant crystallographic orientation and a thickness of one hundred microns or less, the base layer having first and second surfaces;
a tensile stressed metal layer adhered to the base layer above the first surface;
the second surface of the base layer comprising a naturally formed texture comprised of a plurality of facets defined by natural fracture planes within the semiconductor material.

23. The structure of claim 22, wherein the semiconductor material is single crystal silicon (001) and the facets are along (111) planes.

24. The structure of claim 23, wherein the naturally formed texture of the second surface of the base layer is from 10 to 50 μm peak to valley.

25. The structure of claim 22, wherein the naturally formed texture of the second surface of the base layer is from 10 to 50 μm peak to valley.
